(19) United States
(12) Patent Application Publication
(10) Pub. No.: US 2020/0035709 A1
(43) Pub. Date: Jan. 30, 2020

(54) METHOD FOR MANUFACTURING THIN-FILM TRANSISTOR ARRAY SUBSTRATE AND THIN-FILM TRANSISTOR ARRAY SUBSTRATE

(71) Applicant: SHENZHEN CHINA STAR OPTOELECTRONICS TECHNOLOGY CO., LTD., Shenzhen, Guangdong (CN)

(72) Inventors: Maoxia ZHU, Shenzhen, Guangdong (CN); Hongyuan XU, Shenzhen, Guangdong (CN)

(21) Appl. No.: 16/308,631

(22) PCT Filed: Aug. 23, 2018
(86) PCT No.: PCT/CN2018/101840

§ 371 Date: Dec. 10, 2018

(30) Foreign Application Priority Data
Jul. 30, 2018 (CN) 201810853043.2

(51) Int. Cl. H01L 27/12; H01L 29/66; H01L 29/786

(52) U.S. Cl. CPC H01L 27/127; H01L 27/1222; H01L 29/78669; H01L 29/66765; H01L 27/1262

(57) ABSTRACT

The present disclosure provides a method for manufacturing a thin-film transistor array substrate including: providing substrate, disposing a gate electrode, a gate insulation layer, and a semiconductor thin film in sequence; depositing a photoresist layer on the semiconductor thin film and pattern the photoresist layer; stripping the photoresist layer to form a source-drain electrode. The present disclosure further provides a thin-film transistor array substrate manufactured by the above method.

### FIELD OF INVENTION

The present disclosure relates to a display panel technology, more particularly, to a method for manufacturing a thin-film transistor array substrate and a thin-film transistor array substrate.

### BACKGROUND OF INVENTION

In the present thin-film transistor (TFT) liquid crystal display (LCD), TFTs work as a switch. One of the most widely used TFT has three terminals. Two of the terminals are a source electrode and a drain electrode, which are connected to two ends of an active layer disposed on a glass substrate. The electric current followed between the source electrode and the drain electrode is controlled by a voltage applied on a gate electrode. Back channel etched and etch blocking are most used methods for manufacturing TFT on glass substrates. Etch blocking becomes a non-mainstream method due to an extra etch blocking layer is required, therefore manufacturing costs increase because five masks are required in processes. In the meanwhile, back channel etched requires only four masks for manufacturing TFT so manufacturing cost is reduced and the manufacturing efficiency are improved. However, when 4 masks pattern technology are utilized, a channel of the active layer is etched by dry-etching gas during a second dry etching process for forming the source electrode and the drain electrode. Thus, the electrical performance of the semiconductor channel is deteriorated and performance of the TFT array substrate is affected at the same time.

To conclude, the channel of the active layer is etched by dry-etching gas during the second dry etching process of the present four masks pattern technology for forming the source electrode and the drain electrode, so that technical issues are arisen because the performance of the TFT array substrate is deteriorated.

In a present four masks pattern technology, a channel of an active layer is etched by dry-etching gas during the second dry etching process for forming a source electrode and a drain electrode, so that performance of TFT array substrate is deteriorated.

### SUMMARY OF INVENTION

The present disclosure provides a method for manufacturing thin-film transistor array substrate, comprising:

S10 providing a substrate, disposing a gate electrode on the substrate, and depositing a gate insulation layer and a semiconductor thin-film on the gate electrode;
S20 coating a photoresist layer on the semiconductor thin-film, patterning the photoresist layer by gray-scale exposure, and forming a first photoresist block and a second photoresist block wherein the first photoresist block and the second photoresist block are spaced from each other;
S30 removing parts of the semiconductor thin-film which are not covered by the first photoresist block or the second photoresist block to by utilizing an etching process form an active layer;
S40 forming a first partly-photoresist block and a second partly-photoresist block after performing an gray-scale procedure on the first photoresist block and the second photoresist block, wherein the first partly-photoresist block comprises a first sub-block and a second sub-block spaced from each other;
S50 etching the active layer to form transversely etched structures on the active layer and the first partly-photoresist block;
S60 depositing an ohmic contact thin-film layer and a metal layer sequentially on the active layer, the gate insulation layer, the first partly-photoresist block, and the second partly-photoresist block, wherein the ohmic contact thin-film layer and the metal layer covered on the first partly-photoresist block separate from the ohmic contact thin-film layer and the metal layer covered on the second partly-photoresist block;
S70 forming a source-drain electrode by striping the first partly-photoresist block and the second partly-photoresist block.

According to a preferred embodiment of the present disclosure, the S20 comprises:

S201 coating the photoresist layer on the semiconductor thin-film layer by utilizing a coating technology;
S202 forming the photoresist layer having non-uniform thickness by performing gray-scale exposure with a mask from bottom to top of the photoresist layer through the substrate;
S203 forming the first photoresist block and the second photoresist block which are spaced from each other after removing exposed parts of the photoresist layer.

According to a preferred embodiment of the present disclosure, the mask is a half-tone mask or a gray-tone mask.

According to a preferred embodiment of the present disclosure, the gray-scale procedure utilizes oxygen and a length of the gray-scale procedure is between 20 seconds and 100 seconds.

According to a preferred embodiment of the present disclosure, the first photoresist block is thicker than the second photoresist block.

According to a preferred embodiment of the present disclosure, the first partly-photoresist block is thicker than the first photoresist block, the second partly-photoresist block is thicker than the second photoresist block.

According to a preferred embodiment of the present disclosure, the transversely etched structures on the active layer are concave.

According to a preferred embodiment of the present disclosure, the ohmic contact layer comprises amorphous silicon mixed with phosphor, the metal layer comprises copper.

According to a preferred embodiment of the present disclosure, a thickness of the active layer is 30 to 50 nanometers, a thickness of the metal layer is 450 to 500 nanometers.

The present disclosure further provides a thin-film transistor (TFT) array substrate comprising a substrate, a gate electrode, a gate insulation layer, an active layer, an ohmic contact layer, a source-drain electrode metal layer and a passivation layer. The gate electrode disposed on a surface of the substrate. The gate insulation layer disposed on the surface of the substrate, wherein the gate insulation layer covers the gate electrode. The active layer disposed on a surface of the gate insulation layer and comprising a channel, a source doped region and a drain doped region, wherein the active layer is shaped into a gateway connected to the gate electrode. The ohmic contact layer disposed on the source doped region and the drain doped region. The source-drain electrode metal layer disposed on a surface of the ohmic contact layer. The passivation layer disposed on the surface of the gate insulation layer and entirely covering the active layer and the source-drain metal layer.

According to a preferred embodiment of the present disclosure, the ohmic contact layer comprises amorphous silicon mixed with phosphor, the metal layer comprises copper.

According to a preferred embodiment of the present disclosure, a thickness of the active layer is 30 to 50 nanometers, a thickness of the metal layer is 450 to 500 nanometers.

The present disclosure provides a method for manufacturing TFT array substrate and provides a TFT array substrate where the photoresist layer which is formed on the back channel of the TFT array substrate has a non-uniform thickness. Furthermore, the ohmic contact layer and the metal layer are formed by a striping technology. Therefore, the etching happening on the back channel during the second dry etching process for forming a source electrode and a drain electrode is prevented so that the goal to protect the back channel is achieved.

### DESCRIPTION OF THE DRAWINGS

To clarify the technology methods of embodiments from present technology, the following context simply introduces drawing of embodiments or present technology. Obviously, the following drawings are just part of the present disclosure. For a skilled person in the art, other drawings can be obtained on the basis of the following drawing without creative effort.

FIG. 1 is a follow chart of a method for manufacturing thin-film transistor (TFT) array substrate of the present disclosure.

FIG. 1A to 1G illustrate the method for manufacturing thin-film transistor (TFT) array substrate as shown in FIG. 1.

FIG. 2 illustrates a structure of the TFT array substrate of the present disclosure.

### DETAILED DESCRIPTION OF PREFERRED EMBODIMENTS

The illustrations of the following embodiments take the attached drawings as reference to indicate the applicable specific examples of the present disclosure. The mentioned directional terms, such as upper, lower, front, back, left, right, inner, outer, side, etc., are only directions by referring to the accompanying drawings, and thus the used directional terms are used to describe and understand the present invention, but the present invention is not limited thereto. In the drawings, similar modules are numbered with the same reference numbers.

The present disclosure focus on that a channel of an active layer manufactured by a present back etched channel performed by four masks pattern technology is etched by dry-etching gas because there are two dry etching processes. This makes the electric performance of a semiconductor back channel is deteriorated. The present disclosure can solve this defect.

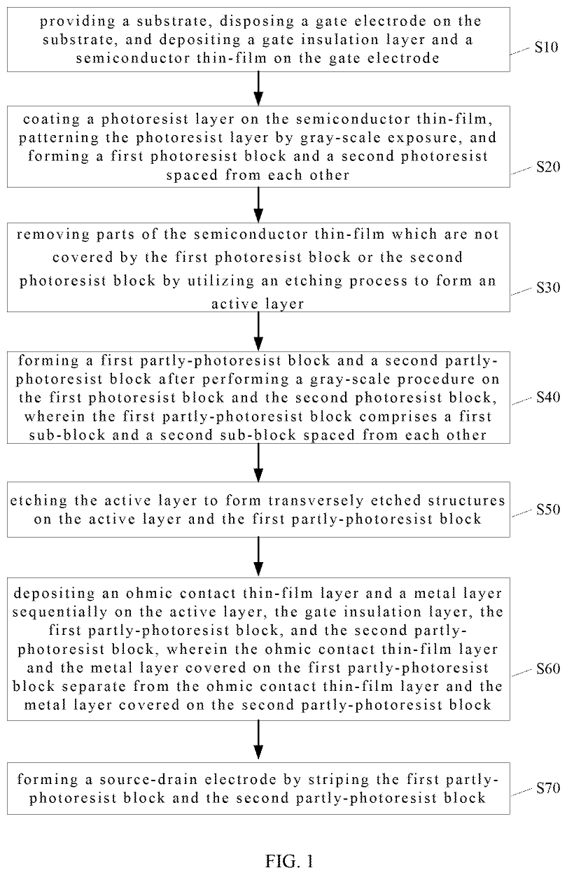

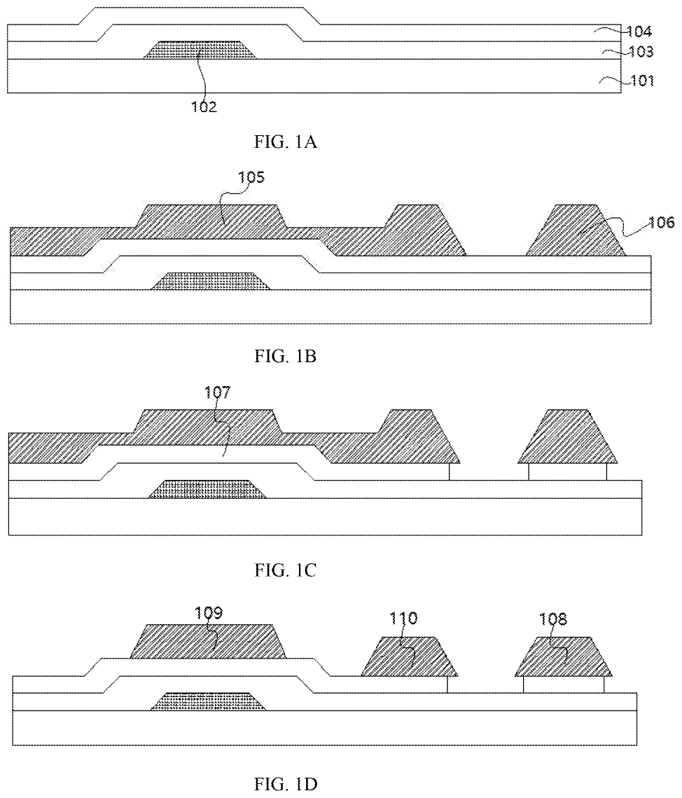

Please refer to FIG. 1, the present disclosure provides a method or manufacturing a thin-film transistor (TFT) substrate which includes the following steps.

S10 provides a substrate 101, disposes a gate electrode 102 on the substrate 101, and deposits a gate insulation layer 103 and a semiconductor thin-film 104 on the gate electrode 102.

More particularly, the S10 further includes the following steps.

Wash the substrate 101 with pure water, hot sulfuric liquid or other wash liquid, where the substrate is a glass substrate. Sputter metal layer on the substrate 101 and form the gate electrode 101 by defining a conductive structure of gate electrode with a mask photolithography process, where the material of the gate electrode 102 is selected from Molybdenum (Mo) or Aluminum-Neodymium (Al—Nd). Utilize vapor deposition process to deposit the gate insulation layer 103 and the semiconductor thin-film 104 on the gate electrode 102. The gate insulation layer 103 includes silicon nitride chemical compound and the thickness of the gate insulation layer 103 is 300 nm. The semiconductor thin-film 104 includes amorphous silicon and the thickness of the semiconductor thin-film 104 is 40 nm as shown in FIG. 1A.

S20 coats a photoresist layer on the semiconductor thin-film 104 and forms a first photoresist block 105 and a second photoresist block 106 by patterning the photoresist layer by gray-scale exposure.

More particularly, the S20 further includes the following steps.

First, utilize a coating technology to coat the photoresist layer and form the first photoresist block 105 and the second photoresist block 106, which are spaced from each other, on the semiconductor thin-film layer 104 by performing exposure from bottom to top of the photoresist layer through the substrate 101 by utilizing a mask. The mask is a half-tone mask or a gray-tone mask which utilizes grating effect to make a first part short of exposure forming thicker photoresist, to make a second part forming thinner photoresist due to exposure, and to make the reset parts of the photoresist entirely removed due to the fully exposure. The first photoresist block 105 is thicker than the second photoresist 106 as shown in FIG. 1B.

S30 removes parts of the semiconductor thin-film 104 which are not covered by the first photoresist block 105 or the second photoresist block 106 by utilizing an etching process to form an active layer 107.

More particularly, the S30 further includes the following steps.

Utilize the first photoresist block 105 and the second photoresist block 106 as a mask to perform a first etching process applying on the semiconductor thin-film 104 for forming a channel structure which is corresponding to the gate electrode 102. Remove parts of the semiconductor thin film 104 which are not covered by the first photoresist block 105 or the second photoresist block 106 to form the active layer 107. The active layer 107 includes a channel, a source doped region, and a drain doped region as shown in FIG. 1C.

S40 forms a first partly-photoresist block and a second partly-photoresist block 108 after performing an gray-scale procedure on the first photoresist block 105 and the second photoresist block 106. The first partly-photoresist block includes a first sub-block 109 and a second sub-block 110 which are spaced from each other.

More particularly, the S40 further includes the following steps.

Perform gray-scale procedure on the first photoresist block 105 and the second photoresist block 106 to remove their thinner parts and thin their thicker parts. Oxygen (O₂) is utilized during the gray-scale procedure and the duration of the gray-scale procedure is between 20 seconds and 100 seconds. Obtain the first partly-photoresist block and the second partly-photoresist block 108 by performing the gray-scale procedure. The first partly-photoresist block includes the first sub-block 109 and the second sub-block 110 which are spaced from each other. As shown in FIG. 1D, the first sub-block 109 is disposed on the surface of the channel of the active layer 107, the second sub-block 110 is disposed on the drain doped region of the active layer 107, and the second partly-photoresist block 108 is disposed on a via hole of the active layer 107.

S50 etches the active layer 107 to form transversely etched structures on the active layer 107 and the first partly-photoresist block.

More particularly, the S50 further includes the following steps.

Form the transversely etched structures resulted from the edge width differences of the active layer 107 and the first partly-photoresist block by adopting gas having same chemical property and adopting the first partly-photoresist block as a mask to perform etching process from all directions on the active layer 107. The active layer 107 of the transversely etched structures shrinks inside. As shown in FIG. 1E, the projection of the first partly-photoresist block corresponding on the TFT array substrate entirely cover the projection of the active layer 107 corresponding on the TFT array substrate.

S60 deposits an ohmic contact thin-film layer 111 and a metal layer 112 sequentially on the active layer 107, the gate insulation layer 103, the first partly-photoresist block, and the second partly-photoresist block 108. The ohmic contact thin-film layer 111 and the metal layer 112 covering on the first partly-photoresist block separate from the ohmic contact thin-film layer 111 and the metal layer 112 covering on the second partly-photoresist block 108.

More particularly, the S60 further includes the following steps.

Deposit the ohmic contact thin-film layer 111 and the metal layer 112 sequentially on the active layer 107, the gate insulation layer 103, the first partly-photoresist block, and the second partly-photoresist block 108. The ohmic contact thin-film layer 111 is disposed on the source doped region and the drain doped region. The ohmic contact thin-film layer 111 and the metal layer 112 covering on the first partly-photoresist block separate from the ohmic contact thin-film layer 111 and the metal layer 112 covering on the second partly-photoresist block 108. In particular, the ohmic contact thin-film layer 111 is formed by amorphous silicon mixed with phosphor by vapor deposition. The ohmic contact thin-film layer 111 and the metal layer 112 covering on the first partly-photoresist block separate from the ohmic contact thin-film layer 111 and the metal layer 112 covering on the second partly-photoresist block 108 due to the transversely etched structures. The first partly-photoresist block and the second partly-photoresist block 108 are covered by the ohmic contact thin-film layer 111 and the metal layer 112. As shown in FIG. 1F, the channel of the active layer 107 is prevented from the second etching due to the existence of the first sub-block 109. The metal layer 112 includes copper. The thickness of the metal layer is 500 nm.

S70 forms a source-drain electrode by striping the first partly-photoresist block and the second partly-photoresist block 108.

More particularly, the S70 further includes the following steps.

First, strip the first partly-photoresist block and the second partly-photoresist block 108 with photoresist stripping fluid so that the ohmic contact thin-film layer 111 and the metal layer 112 covering on the first partly-photoresist block and the second partly-photoresist block 108 are striped together. The source-drain electrode is formed by the metal layer 112 as shown in FIG. 1G.

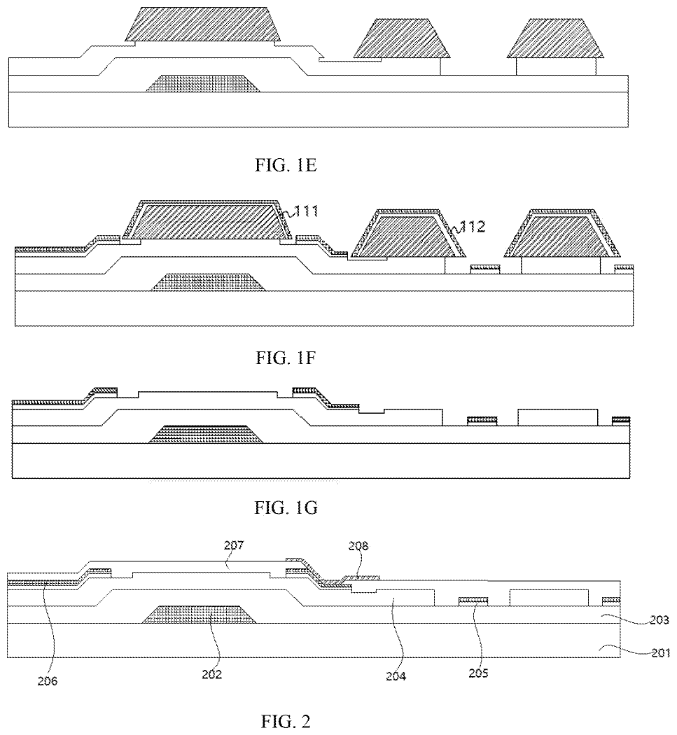

According to above-mentioned manufacturing method, a TFT array substrate can be obtained by adopting a back channel etching process. Please refer to FIG. 2. A gate electrode 202 is disposed on a glass substrate 201. A gate insulation layer 202 including silicon nitride and an active layer 204 including amorphous silicon are sequentially formed in the gate electrode 202. A non-continuous ohmic contact layer 205, which exposing the channel and insulation layer, and a source-drain electrode metal layer 206 are disposed on the active layer 204. The ohmic contact layer 205 and the source-drain electrode metal layer 206 entirely shelter and fit the source doped region and the drain doped region of the active layer 204. A passivation layer 207 including silicon nitride is disposed on the source-drain electrode metal layer 206. An indium tin oxide (ITO) layer is disposed on the passivation layer 207. The ITO layer forms a pixel electrode 208.

The benefits of the present disclosure are providing a method for manufacturing a TFT array substrate and providing a TFT array substrate to form a photoresist layer having non-uniform thickness on the back channel of the TFT array substrate and form an ohmic contact layer and a source-drain electrode metal layer by striping technology, so that the back channel is prevented from etching during the second dry etching process for forming the source electrode and the drain electrode.

To conclude, the above-mentioned embodiments are utilized to exemplify rather than limit the technology concept of the present disclosure. Any modification and variation which can be completed by a skilled person in the art on the basis of the specification should fall into the scope of the claims protected by the present disclosure.

1. A method for manufacturing a thin-film transistor (TFT) array substrate, wherein the method comprises:
S10 providing a substrate, disposing a gate electrode on the substrate, and depositing a gate insulation layer and a semiconductor thin-film on the gate electrode;
S20 coating a photoresist layer on the semiconductor thin-film, patterning the photoresist layer by gray-scale exposure, and forming a first photoresist block and a second photoresist block wherein the first photoresist block and the second photoresist block are spaced from each other;
S30 removing parts of the semiconductor thin-film which are not covered by the first photoresist block or the second photoresist block by utilizing an etching process to form an active layer;
S40 forming a first partly-photoresist block and a second partly-photoresist block after performing a gray-scale procedure on the first photoresist block and the second photoresist block, wherein the first partly-photoresist block comprises a first sub-block and a second sub-block spaced from each other;
S50 etching the active layer to form transversely etched structures on the active layer and the first partly-photoresist block;
S60 depositing an ohmic contact thin-film layer and a metal layer sequentially on the active layer, the gate insulation layer, the first partly-photoresist block, and the second partly-photoresist block, wherein the ohmic contact thin-film layer and the metal layer covered on the first partly-photoresist block separate from the ohmic contact thin-film layer and the metal layer covered on the second partly-photoresist block;
S70 forming a source-drain electrode by striping the first partly-photoresist block and the second partly-photoresist block.

2. The method for manufacturing the TFT array substrate according to claim 1, wherein the S20 comprises:
S201 coating the photoresist layer on the semiconductor thin-film layer by utilizing a coating technology;
S202 forming the photoresist layer having non-uniform thickness by performing gray-scale exposure with a mask from bottom to top of the photoresist layer through the substrate;
S203 forming the first photoresist block and the second photoresist block spaced from each other after removing exposed parts of the photoresist layer.

3. The method for manufacturing the TFT array substrate according to claim 2, wherein the mask is a half-tone mask or a gray-tone mask.

4. The method for manufacturing the TFT array substrate according to claim 1, wherein the gray-scale procedure utilizes oxygen and a length of the gray-scale procedure is between 20 seconds and 100 seconds.

5. The method for manufacturing the TFT array substrate according to claim 1, wherein the first photoresist block is thicker than the second photoresist block.

6. The method for manufacturing the TFT array substrate according to claim 5, wherein the first partly-photoresist block is thicker than the first photoresist block, the second partly-photoresist block is thicker than the second photoresist block.

7. The method for manufacturing the TFT array substrate according to claim 1, wherein the transversely etched structures on the active layer are concave.

8. The method for manufacturing the TFT array substrate according to claim 1, wherein the ohmic contact layer comprises amorphous silicon mixed with phosphor, the metal layer comprises copper.

9. The method for manufacturing the TFT array substrate according to claim 1, wherein a thickness of the active layer is 30 to 50 nanometers, a thickness of the metal layer is 450 to 500 nanometers.

10. A thin-film transistor (TFT) array substrate, comprising;
a substrate;
a gate electrode disposed on a surface of the substrate;
a gate insulation layer disposed on the surface of the substrate, wherein the gate insulation layer covers the gate electrode;
an active layer disposed on a surface of the gate insulation layer and comprising a channel, a source doped region and a drain doped region, wherein the active layer is shaped into a gateway connected to the gate electrode;
an ohmic contact layer disposed on the source doped region and the drain doped region;
a source-drain electrode metal layer disposed on a surface of the ohmic contact layer;
a passivation layer disposed on the surface of the gate insulation layer and entirely covering the active layer and the source-drain metal layer.

11. The TFT array substrate according to claim 10, wherein the ohmic contact layer comprises amorphous silicon mixed with phosphor, the metal layer comprises copper.

12. The TFT array substrate according to claim 10, wherein a thickness of the active layer is 30 to 50 nanometers, a thickness of the metal layer is 450 to 500 nanometers.
